(19) United States
(12) Patent Application Publication
(10) Pub. No.: US 2022/0087047 A1
(43) Pub. Date: Mar. 17, 2022

(54) CABINET WITH FRAME MEMBERS ADAPTED AS CABLEWAYS

(71) Applicants: Enconnex LLC, Reno, NV (US); Shanghai Ruiji Technology Co., LTD., Shanghai (CN)

(72) Inventors: Chun Yang FAN, Shanghai (CN); Yu ZHANG, Fremont, CA (US)

(21) Appl. No.: 17/212,538

(22) Filed: Mar. 25, 2021

(30) Foreign Application Priority Data
Sep. 11, 2020 (CN) 202021985212.7

(51) Int. Cl. H05K 7/14; A47B 96/14; H05K 7/18

(52) U.S. Cl. CPC H05K 7/1491; A47B 2220/0091; H05K 7/18; A47B 96/1466

(57) ABSTRACT

Racks and cabinets for housing information technology equipment are disclosed. In these racks and cabinets, a number of upright members are connected to cross-members to define a rectilinear frame. Mounting rails are coupled directly or indirectly to the upright members to carry the equipment. Each of the upright members defines an interior compartment along its length with an opening that spans at least a majority of the width of the upright member. In many embodiments, the width of the opening will span 70%, 80%, or more of the width of the upright member. The interior compartments of the upright members are configured as cable raceways and spaces for storing support equipment.

### CROSS-REFERENCE TO RELATED APPLICATIONS

This application claims priority to Chinese Utility Model No. 202021985212.7 filed Sep. 11, 2020, the contents of which are incorporated by reference herein in their entirety.

### TECHNICAL FIELD

The invention relates to cabinets and racks for housing computing equipment.

### BACKGROUND

A data center is a facility that houses computing equipment. Such facilities are the physical infrastructure behind so-called cloud computing, form the backbone of the Internet, and are usually filled with row after row of racks or cabinets that are adapted to hold computing components, such as servers, network routers, and switches, as well as uninterruptible power supplies and other components needed to keep the computing components running. While racks and cabinets that hold computing equipment are most numerous in data centers, many businesses and other organizations with significant information technology infrastructure have at least one rack or cabinet on site to house the necessary equipment.

Racks and cabinets are intended to provide quick, modular mounting and removal of components, as well as ample airflow for ventilation and easy access for connection of wires and cables. They are usually made to standardized dimensions using industry-defined units. For example, most racks and cabinets are described and dimensioned in terms of “rack units” (U). The height of one rack unit has been standardized to 44.45 mm (1.75 in). Total rack and cabinet heights of 42 U and 45 U are common, although other heights are available. Server racks and cabinets usually have a width on the order of 19 in (482.6 mm), although racks and cabinets meant to accommodate switches are typically wider, in order to allow more room for connecting cables.

Whether located in a data center or in an equipment room at some other site, space is almost always at a premium. Cabinets and racks are expected to have a small footprint and to make the most efficient possible use of space. Unfortunately, the typical construction of a rack or cabinet wastes space. As one example, FIG. 1 is a cross-section of a prior art cabinet frame member 10 made by folding sheet metal. As is shown in FIG. 1, the frame member 10 has an open cross-section that encloses considerable area; however, the folds in the metal prevent the enclosed area from being used for any other purposes. Some cabinet frame members are fully tubular, with a fully enclosed interior space that, although closed, presents the same issue: wasted internal space. Taken together, the volume of space consumed by the frame members is considerable.

### BRIEF SUMMARY

Aspects of the invention relate to racks and cabinets for housing information technology equipment. In these racks and cabinets, a number of upright members are connected to cross-members to define a rectilinear frame. Mounting rails are coupled directly or indirectly to the upright members to carry the equipment. Each of the upright members defines an interior compartment along its length with an opening that spans at least a majority of the width of the upright member. In many embodiments, the width of the opening will span 70%, 80%, or more of the width of the upright member.

The upright members may be relatively wide, as compared with the upright members of other such cabinets. The interior compartment of each upright member is typically configured as a cableway and a space for mounting support equipment, like power distribution units. At least one surface of the interior compartment may have openings and/or other structures that configure it to be used as a tie-down plate and cable organizer. For these reasons, the openings of the interior compartments of the upright members will usually face inwardly. Front and rear upright members may differ in the configurations of their interior spaces.

The upright members themselves are usually constructed of folded sheet metal, with the number of bends intended to increase the rigidity and load-carrying capacity of the resulting beam. In some cases, the arrangement of the folds may be such that the cross-section of the resulting upright member has no axis about which it is symmetrical.

Other aspects, features, and advantages of the invention will be set forth in the description that follows.

### BRIEF DESCRIPTION OF THE DRAWING FIGURES

The invention will be described with respect to the following drawing figures, in which like numerals represent like features throughout the description, and in which:

FIG. 1 is a cross-sectional view of a prior art cabinet support member;

FIG. 2 is a perspective view of a cabinet according to one embodiment of the invention;

FIG. 3 is an exploded perspective view of the cabinet of FIG. 2;

FIG. 4 is a bottom plan view of the cabinet of FIG. 2;

FIG. 5 is a cross-sectional view of one of the support members of the cabinet of FIG. 2, illustrating the order of the folds that create the support member; and

FIG. 6 is a front elevational view of a cabinet according to another embodiment of the invention.

### DETAILED DESCRIPTION

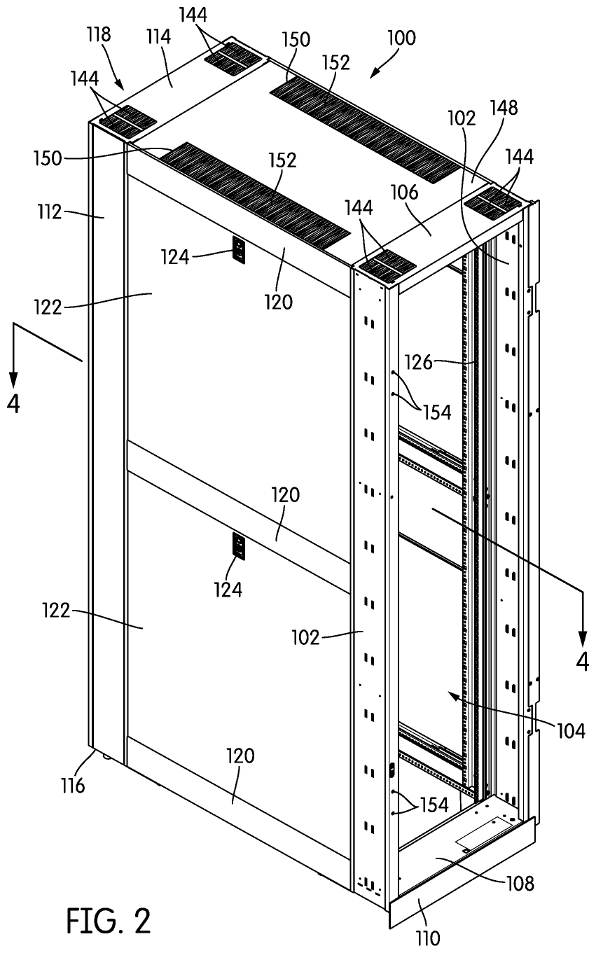

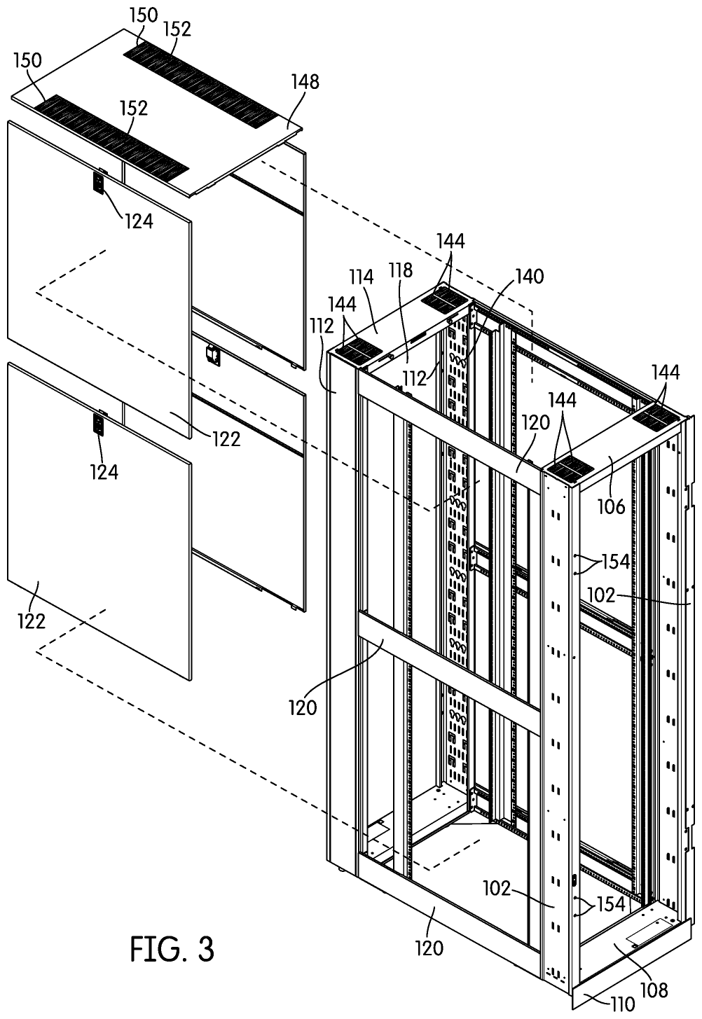

FIG. 2 is a perspective view of a cabinet, generally indicated at 100, according to one embodiment of the invention. FIG. 3 is an exploded perspective view of the cabinet 100.

As shown, the cabinet 100 is rectilinear in overall shape. Generally speaking, the cabinet 100 is comprised of a number of frame members and a number of panels that are mounted on the frame members to enclose the cabinet 100. More specifically, a pair of upright front members 102 flank the front opening 104 and are connected together into a rectangular front frame by shorter upper and lower frame members 106, 108. A front plate 110 is installed over the lower frame member 108. The rear portion of the cabinet 100 has a similar arrangement, with a pair of upright frame members 112 spaced from one another and connected by upper and lower frame members 114, 116. The upright frame members 112 flank the rear opening 118.

Cross members connect the front and rear of the cabinet 100. Specifically, three cross members 120 extend from each upright front member 102 to its corresponding upright rear member 112, for a total of six cross members 120. The arrangement of the cross members 120 is such that, on each side of the cabinet 100, one cross member 120 aligns with the tops of the upright members 102; one cross member 120 aligns with the bottoms of the upright members 102; and one cross member 120 aligns with the midpoint between top and bottom.

In this embodiment, upper and lower side panels 122 mount between the cross members 120. Each side panel 122 has a latching mechanism 124 that secures it to at least one of the cross members 120. This renders the side panels 122 removable in use. The cabinet 100 also includes a removable upper cover or roof 148. The roof 148 is rectangular in overall shape and includes a long, rectangular cut-out 150 in each of its long sides. The cut-outs 150 are filled with brush panel 152.

The advantage of this configuration of the roof 148, with its large, extensive brush panel 152, is that the components within the cabinet 100 can be wired as needed before the roof 148 is installed, with the cables from the components simply placed within the brush panels 152 when the roof 148 is installed.

In the illustrated embodiment, the front opening 104 and rear opening 118 are open; however, in other embodiments, a door may be installed over one or both openings 104, 118. More specifically, both the front and rear upright members 102, 112 have openings 154 provided in outer portions. The openings are sized and spaced for the installation of hinges or other door-supporting structure. If a door or doors are used, the front and back of the cabinet 100 may have different styles of doors. For example, the front of the cabinet 100 may have a single hinged door, while the rear of the cabinet 100 may use a pair of so-called French doors, each one shallower than a single door. This sort of arrangement may allow for reduced space in the rear of the cabinet 100.

The upright front members 102 are connected to standard mounting rails 126 sized to accept rack-mount equipment. In the illustrated embodiment, the mounting rails 126 have a series of standard openings into which equipment can be bolted. These openings are of a standard type and arranged at a standard pitch. The mounting rails 126 may be, for example, EIA standard 10/32 tapped mounting rails, or universal mounting rails, which use square openings. In the illustrated embodiment, the mounting rails 126 are universal mounting rails.

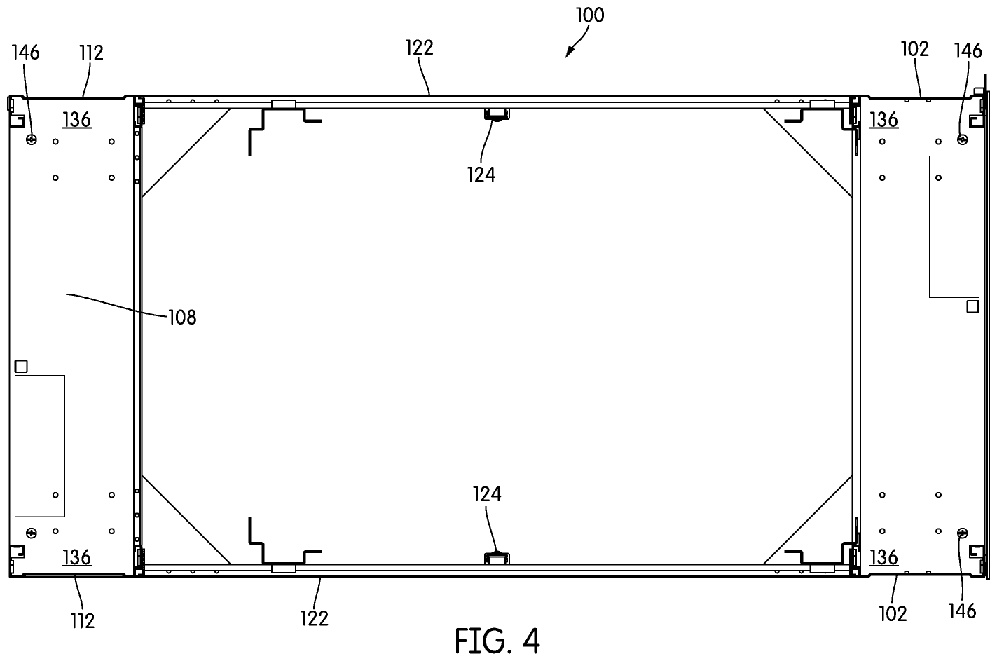

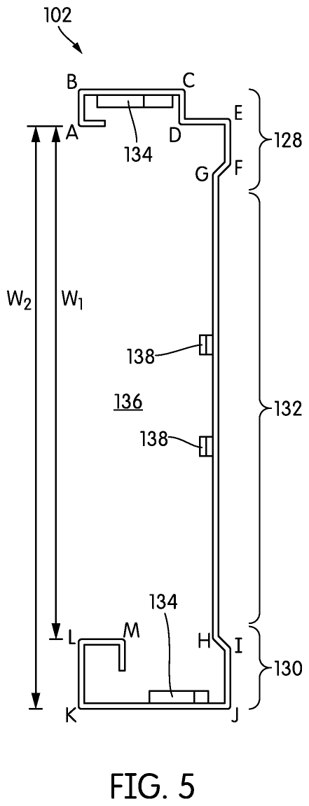

The cabinet 100 thus has the features needed to mount standard rack-mount equipment. Its internal dimensions may be standardized, and its height may also meet industry standards. However, as can be seen in FIG. 4, a cross-sectional view taken through Line 4-4 of FIG. 3, the upright front members 102 and the upright rear members 112 have a unique, open shape. The shape of these members 102 can be seen more clearly in FIG. 5, a cross-sectional view of an upright member 102 in isolation. As will be explained below in more detail, the upright rear members 112 have the same or essentially the same cross-sectional shape, but differ in certain other features.

The upright member 102 comprises a single sheet of metal folded a number of times to create the shape shown in FIG. 5. In the view of FIG. 5, the folds are labeled A through M, in the order in which they are made during one exemplary manufacturing process.

In the illustrated embodiment, the upright members 102 are not symmetrical about any given axis of symmetry. For purposes of description only, the upright member 102 can be divided into three portions: a first side portion 128, a second side portion 130, and a central portion 132 extending between the first side portion 128 and the second side portion 130. The central portion 132 of this embodiment is unbent and extends in a line between the first side portion 128 and the second side portion 130.

The overall contours, number of bends, and bend locations in the first side portion 128 and the second side portion 130 are chosen to provide a balance between structural rigidity and manufacturability. The bends A-M in the first side portion 128 and the second side portion 130 provide stability and structural rigidity. As those of skill in the art will appreciate, by and large, the most basic way to increase the loading capacity is to increase the number of bends in the upright member 102. Bends may serve other purposes as well, for example, by providing space or structure for the upright member 102 to connect with other structures of the cabinet 100. Additionally, the terminal bends A, B, L and M on each side 128, 130 provide a measure of safety by folding the edges of the piece of sheet metal that forms the upright member 102 inward and away from casual contact, in order to avoid any issues with rough or sharp edges.

Notably, despite the fact that the upright member 102 defines a number of bends, and the edges of the upright member 102 are bent inward, the upright member 102 does not define any closed shapes in its cross-section. The areas that are bent inward on the first side portion 128 and the second side portion 130 and come closest to full closure are but a minor portion of the width of the upright member 102. In other embodiments, the free edges of the upright member 102 may be crimped or closed, but in any case, the upright member 102 is broad with a large opening.

For example, the opening width, W₁ in FIG. 5, may be on the order of 137.5 mm (5.4 inches), while the major width of the upright member 102, W₂ in FIG. 5, is 157 mm (6.2 inches). (A small portion of the width of the first side 128 is excluded from this measurement because it contains punched, raised openings 134 that are used to secure the upright member 102 to the cross-members 120. As can be seen in FIG. 5, the second side 130 has similar openings 134.) Thus, in this embodiment, the opening width W₁ is approximately 87.5% of the overall width W₂. In various embodiments of the invention, the opening may be at least 70%, 75%, 80%, etc. of the overall width. Thus, the opening width W₁ is a preferably a large percentage of the total width W₂, typically at least a majority of the total width W₂, depending on the exact configuration and cross-sectional shape of the upright member 102. With this configuration, each upright member 102 essentially defines an interior compartment, with the central portion 132 serving as an outward wall and the first side 128 and second side 130 serving as generally perpendicularly-arising front and rear walls.

Additionally, it is helpful if the opening width W₁ is large enough that the interior space 136 defined by the upright member 102 is hand-accessible, i.e., the opening width W₁ is large enough for a person to comfortably reach a hand into it and manipulate any cables or other items within the interior space 136. This may mean that in some embodiments, the opening has a minimum width of, e.g. 90-100 mm (3.5-3.9 in). As can be seen in FIGS. 2-4, the interior space 136 is open to the interior of the cabinet 100. This is in contrast to many prior-art cabinets of this type, in which openings in beams open outward.

While this description focuses on forming the upright members 102, 112 from sheet metal, for example, 14 gauge sheet metal, other manufacturing processes could be used. For example, the upright members 102, 112 and other frame members could be extruded, with additional operations (e.g., drilling, punching, stamping, etc.) used to form openings 134 and other features.

Because the interior space 136 is accessible from the interior of the cabinet 100, it can be put to use. More specifically, the interior space 136 in each of the upright members 102 can be used as a raceway for wires and cables. As can be seen particularly in FIGS. 2-3, the central portion 132 of the upright members 102, 112 may have various patterns of slots 138 and openings 140 for power distribution cables, so that the central portions 132 of the upright members 102 can serve as cable organizers and tie-down plates. As is shown in FIG. 3, the front and rear upright members 102, 112 differ in their patterns of slots 138 and openings 140, but are otherwise generally identical—although that need not be the case in all embodiments. Because the upright members 102 serve as cable raceways, the upper frame members 106, 114 have brush panels 144 aligned over the interior spaces 136 of the upright members 102 so that cables can enter and exit the cabinet 100.

The orientation of the upright members 102, 112 relative to the other components of the cabinet 100 can best be seen in FIG. 4. When the cabinet 100 is assembled, the open spaces 136 of the two upright front members 102 face each other, as do the open spaces of the two upright rear members 112. While the description above focuses on the use of the open spaces 136 in the upright members 102, 112 as cableways, they may also be used to house power distribution units and other such support components. Overall, the upright members 102, 112 with their open spaces 136 increase the useable internal space within the cabinet 100 without increasing the overall depth of the cabinet 100. This may also have the effect of reducing the amount of time it takes to install, operate, and maintain components placed in the cabinet 100, because connections are easier to make and maintain with the upright members 102, 112 serving as organizers and tie down plates for cabling and other support components.

FIG. 4 also shows that the cabinet 100 may have other traditional components, such as leveling feet 146 that insert through the lower frame members 108. In some embodiments, the cabinet 100 may have both leveling feet 146 and casters, making it possible to move the cabinet 100 relatively easily. As was noted briefly above, the major frame members 102, 106, 108, 112, 120 of the cabinet may bolt together or be secured together with another form of fasteners, rather than being welded. This may make it less expensive to transport the cabinet 100 after manufacture and prior to installation because, as compared with a cabinet that is entirely or substantially welded, a cabinet 100 according to embodiments of the invention can be shipped disassembled and assembled on site.

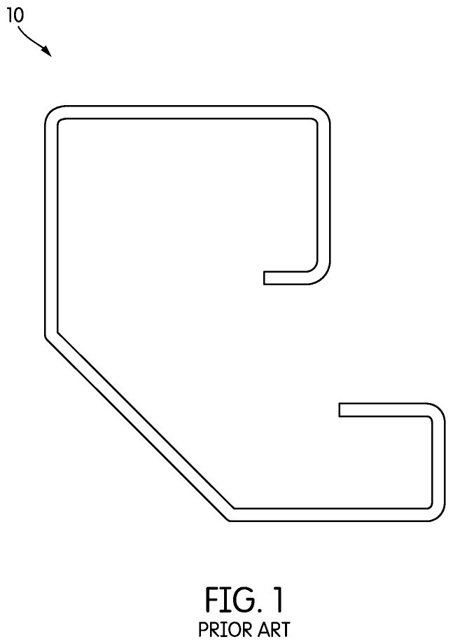

The frame of the cabinet 100 of FIGS. 1-5 may be, e.g., 0.6 m (2 ft) wide, 1.2 m (4 ft) deep, and 2.2 m (7.2 ft) high. However, these dimensions may vary from embodiment to embodiment. For example, as was described above, cabinets and racks may have varying heights denominated in rack units.

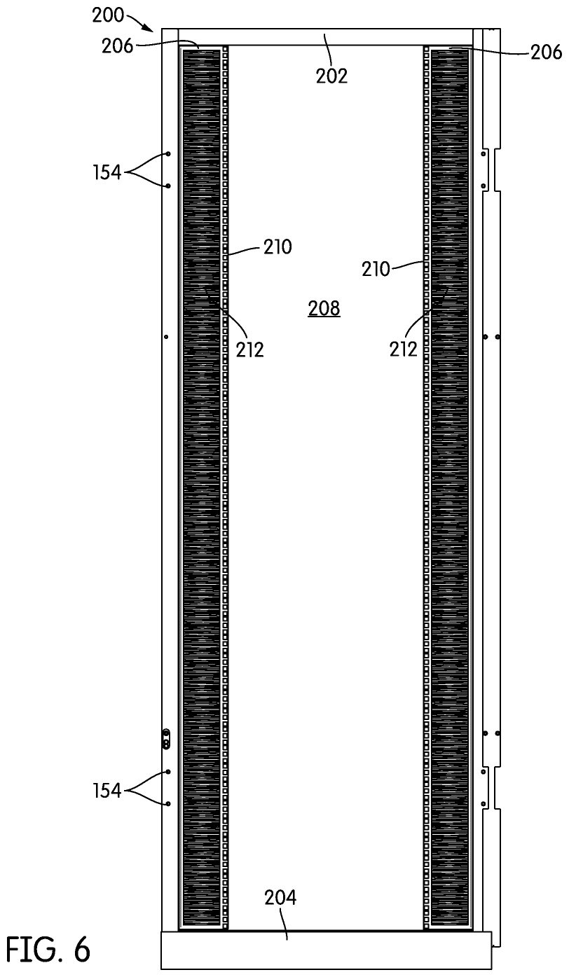

Cabinets and racks according to embodiments of the invention may also be made in other sizes to accommodate other components. As was noted briefly above, cabinets and racks that house switches, which are usually connected to many cables, are often wider to accommodate those cables. To that end, FIG. 6 is a front elevational view of a cabinet, generally indicated at 200, according to another embodiment of the invention. The cabinet 200 may be considered to be generally identical to the cabinet 100 described above, with the same open frame members 102, 112. However, the cabinet 200 is intended for switches, routers, and other such components that require extensive connections to cabling.

Because the cabinet 200 is designed for components that require extensive cabling, it has a wider frame than the cabinet 100 described above. That is, the upper and lower frame members 202, 204 are longer than in the cabinet 100, creating additional internal space along the sides of the cabinet 200.

In order to provide the correct width for mounting components, a pair of front panels 206 are connected to the frame of the cabinet 200 and extend inwardly, into the front opening 208 of the cabinet 200. The inward edges of the front panels 206 carry mounting rail structure 210 that, in this case, are universal mounting rails. The majority of the area of the front panels 206 comprises brush panel 212. Brush panel 212 allows for increased airflow and also allows cables to pass through, if needed.

Although much of the description above pertains to cabinets, aspects of the invention also relate to racks, and racks may have many, if not all, of the features of a cabinet. A rack according to an embodiment of the invention may look much like cabinet 100 without its side panels 122, as shown in FIG. 3.

While the invention has been described with respect to certain embodiments, the description is intended to be exemplary, rather than limiting. Modifications and changes may be made within the scope of the invention, which is defined by the appended claims.

What is claimed is:

1. A rack or cabinet, comprising:
four upright members, each of the upright members having a broad, open cross-sectional shape with an interior compartment along its length that opens into an opening with a width that is at least a majority of a width of the upright member;
a plurality of cross-members connected to and between the four upright members, such that the rack or cabinet defines a rectilinear frame; and
mounting rails coupled directly or indirectly to the four upright members.

2. The rack or cabinet of claim 1, wherein the rack or cabinet is a cabinet and further comprises one or more body panels adapted to be secured between ones of the plurality of cross-members.

3. The cabinet of claim 2, wherein each of the one or more body panels comprises a latching mechanism adapted to secure the body panel to the ones of the plurality of cross-members.

4. The rack or cabinet of claim 1, wherein the interior compartment is configured as a raceway for cabling.

5. The rack or cabinet of claim 4, wherein the openings in each of the upright members open in an inward direction, facing into the rack or cabinet.

6. The rack or cabinet of claim 5, wherein each of the upright members further comprises:
a broad central portion; and first and second side portions that arise generally perpendicularly from the central portion.

7. The rack or cabinet of claim 6, wherein the central portion comprises a plurality of openings or other engaging structures that configure the central portion as a tie-down plate.

8. The rack or cabinet of claim 7, wherein each of the first and second side portions contain one or more bends in their respective cross-sections.

9. The rack or cabinet of claim 8, wherein the cross-section of each of the four upright members has no axis of symmetry.

10. The rack or cabinet of claim 1, wherein the width of the opening is at least 70% of the width of the upright member.

11. The rack or cabinet of claim 1, wherein the width of the opening is at least 80% of the width of the upright member.

12. The rack or cabinet of claim 1, further comprising a top panel, the top panel having sections of brush panel therein.

13. The rack or cabinet of claim 12, wherein the sections of brush panel are located along side edges of the top panel.

14. A rack or cabinet, comprising:
four upright members, each of the upright members having a broad, open cross-sectional shape with an interior compartment along its length that opens into an opening with a width that is at least a majority of a width of the upright member, the openings of the four upright members arranged such that the opening in a first of the four upright members faces the opening in a second of the four upright members across a width of the rack or cabinet;
a plurality of cross-members connected to and between the four upright members, such that the rack or cabinet defines a rectilinear frame; and
mounting rails coupled directly or indirectly to the four upright members.

15. The rack or cabinet of claim 14, wherein the rack or cabinet is a cabinet and further comprises one or more body panels adapted to be secured between ones of the plurality of cross-members.

16. The cabinet of claim 15, wherein each of the one or more body panels comprises a latching mechanism adapted to secure the body panel to the ones of the plurality of cross-members.

17. The rack or cabinet of claim 14, wherein the interior compartment is configured as a raceway for cabling.

18. The rack or cabinet of claim 17, further comprising brush panels in top members of the rack or cabinet, the brush panels aligned with the interior compartments of the four upright members.

19. The rack or cabinet of claim 14, wherein each of the four upright members comprises a piece of bent sheet metal.

20. The rack or cabinet of claim 14, wherein the plurality of cross-members are secured to the four upright members with fasteners.

21. The rack or cabinet of claim 14, wherein each of the upright members further comprises:
a broad central portion; and first and second side portions that arise generally perpendicularly from the central portion.

22. The rack or cabinet of claim 21, wherein the central portion comprises a plurality of openings or other engaging structures that configure the central portion as a tie-down plate.
